(19) United States
(12) Patent Application Publication
(10) Pub. No.: US 2020/0241608 A1
(43) Pub. Date: Jul. 30, 2020

(54) CONVERTER BOARD

(71) Applicant: HEWLETT PACKARD ENTERPRISE DEVELOPMENT LP, Houston, TX (US)

(72) Inventor: Hung ting Ko, Taipei (TW)

(21) Appl. No.: 16/260,541

(22) Filed: Jan. 29, 2019

(51) Int. Cl. G06F 1/18; G06F 13/40; H05K 7/14; H01R 12/72; H01R 12/70

(52) U.S. Cl. CPC G06F 1/185; G06F 13/4068; G06F 13/409; G06F 2213/0026; H05K 7/1408; H01R 12/725; H01R 12/7058; G06F 1/184

(57) ABSTRACT

A converter board, comprising: a printed circuit board, wherein the printed circuit board includes a cutout to form two opposing sides and an end; a guiderail attached to each opposing end, the guiderails to accept an option card; an end connector attached to the end, the end connector to connect to the option card when the option card is fully inserted into the cutout; and an edge connector to connect the converter board to a system, wherein the edge connector is connected to the end connector.

### BACKGROUND

Computing devices may utilize option cards. In some cases, new option cards may connect to computing devices via various connectors. The connectors may be disposed on the motherboard of some computing devices. In some cases, the connectors may not be standard for all computing devices. In other words, some computing devices may not include the connectors for the new option card. Some computing devices may not be able to utilize the new option cards, due to lack of non-standard connectors or due to lack of motherboard real estate.

### BRIEF DESCRIPTION OF THE DRAWINGS

Non-limiting examples of the present disclosure are described in the following description, read with reference to the figures attached hereto and do not limit the scope of the claims. In the figures, identical and similar structures, elements or parts thereof that appear in more than one figure are generally labeled with the same or similar references in the figures in which they appear. Dimensions of components and features illustrated in the figures are chosen primarily for convenience and clarity of presentation and are not necessarily to scale. Referring to the attached figures:

FIG. 1 is a block diagram of a converter board, according to an example;

FIG. 2A is a schematic view of a converter board, according to an example;

FIG. 2B is another schematic view of the converter board, according to an example;

FIG. 3 is a schematic view of a converter board with an option card, according to an example;

FIG. 4 is a schematic view of a portion of a computing device, a converter board, and other boards, according to an example; and

FIG. 5 is a flow chart of a method to install a network interface card (NIC) into a peripheral component interconnect express (PCIe) converter board, according to an example.

### DETAILED DESCRIPTION

In the following detailed description, reference is made to the accompanying drawings which form a part hereof, and in which is depicted by way of illustration specific examples in which the present disclosure may be practiced. It is to be understood that other examples may be utilized and structural or logical changes may be made without departing from the scope of the present disclosure.

Computing devices may utilize option cards. In some cases, new option cards may connect to computing devices via various connectors. The connectors may be disposed on the motherboard of some computing devices. In some cases, the connectors may not be standard for all computing devices. In other words, some computing devices may not include the connectors for the new option card. Some computing devices may not be able to utilize the new option cards, due to lack of non-standard connectors or due to lack of motherboard real estate (for example, where option card connectors are directly connected to the motherboard). For example, an Open Compute Platform (OCP) Network Interface Card (NIC) version 3.0 (OCP NIC 3.0) may connect to a system via a small form factor-technology affiliate-1002 (SFF-TA-1002) connector. In such examples, the SFF-TA-1002 may be directly disposed on the motherboard of a computing device. Further, some computing devices may not include the SFF-TA-1002 connection, thus precluding those computing devices from utilizing the OCP NIC 3.0.

Examples described herein include a converter board. The converter board may include a gap, cutout, or space defined by two opposing sides and an end connector. The converter board may include an opening opposite the end connector. The opening in the converter board may allow for the insertion or addition of an option card, The two opposing sides of the converter board may each include a guide rail. The guide rail may guide the option card into the converter board. In other words, the guide rails may assist with insertion or addition of the option card. The end connector of the converter board may connect to a connector of the option card (a connector such as an edge connector). The end connector of the converter board may connect, via electrical wiring, traces, or other means, to the edge connector of the converter board. The edge connector of the converter board may connect to a socket, slot, interface, or connector of a computing device.

Accordingly, various examples include a converter board comprising a printed circuit board (PCB). The PCB may include a cutout. The cutout may form two opposing sides and an end. The cutout may include an opening opposite the end. Each opposing side of the cutout may include a guiderail, The guiderails may accept an option card. The end of the converter board may include an end connector. The option card may be fully inserted into the cutout to connect to the end connector or, in other words, the option card may connect to the end connector. The converter board may include an edge connector to connect the converter board to a computing device or system. The edge connector may be connected to the end connector

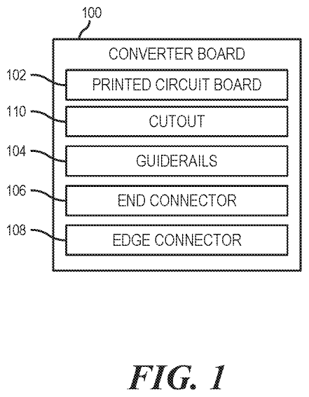

FIG. 1 is a block diagram of a converter board 100, according to an example. The converter board 100 may be made of a PCB 102. The PCB 102 may include a cutout 110, space, or gap formed in the PCB 102. The cutout 110 may be defined by two opposing sides and an end. Each opposing side may include a guiderail 104. The guiderails 104 may accept an option card or guide an option card into the cutout 110 as the option card is inserted into the cutout 110. The end of the cutout may include an end connector 106. The end connector 106 may be a socket, slot, interface, or connector to connect to the option card. The end connector 106 may be connected to an edge connector 108 of the converter board 100 (thus, routing the option card to a computing device that the converter board 100 may be connected to).

As used herein, a “computing device” may be a storage array, storage device, storage enclosure, server, desktop or laptop computer, computer cluster, node, partition, virtual machine, or any other device or equipment including a controller, a processing resource, or the like. In examples described herein, a “processing resource” may include, for example, one processor or multiple processors included in a single computing device or distributed across multiple computing devices. As used herein, a “processor” may be at least one of a central processing unit (CPU), a semiconductor-based microprocessor, a graphics processing unit (GPU), a field-programmable gate array (FPGA) to retrieve and execute instructions, other electronic circuitry suitable for the retrieval and execution instructions stored on a machine-readable storage medium, or a combination thereof.

As used herein, a “machine-readable storage medium” may be any electronic, magnetic, optical, or other physical storage apparatus to contain or store information such as executable instructions, data, and the like. For example, any machine-readable storage medium described herein may be any of Random Access Memory (RAM), volatile memory, non-volatile memory, flash memory, a storage drive (e.g., a hard drive), a solid state drive, any type of storage disc (e.g., a compact disc, a DVD, etc.), and the like, or a combination thereof. Any machine-readable storage medium described herein may be non-transitory.

As used herein, “printed circuit board” or PCB may refer to a board that mechanically supports and electrically connects components. The board may connect components via tracks, pads, tracing, vias, layers, etching, soldering, and/or various other means.

As used herein, “option card” may refer to a card that is an option or add-on for a computing device. In other words, an option card may include, but not be limited to, an add-in component, a peripheral component, a controller, a PCIe card, a NIC, or a machine-readable storage medium. An option card may be hot pluggable, hot swappable, or neither.

As used herein, “peripheral component interconnect express” or PCIe refers to the high speed serial connection standard of the same name (as in, PCIe), A PCIe card may refer to a PCB that includes a PCIe edge connector or mezzanine connector. In other words, a PCIe card may connect to a computing device via a PCIe connector on a riser on the computing devices motherboard or on a mezzanine connector on the computing devices motherboard.

As used herein, “network interface card” or NIC may refer to a type of option card. A NIC may connect a computing device to a network (intranet or internet). A NIC may include a various number and type of ports. For example, a NIC may include two Ethernet ports. In another example, a NIC may include one fibre channel port. A NIC may be hot pluggable, hot swappable, or neither.

As used herein, “hot plug” may refer to the act of adding a component or components to a system while the system is powered on and/or running. Further, hot plug may include the continued operation of the system without significant interruption when the component or components are added. In other words, a device may be added to a system while the system is operating and the user or the system itself may perform an administrative task, so that the added device can be utilized. Hot plug may also be referred to with terms such as, hot pluggable, hot plugging, or hot pluggability. For example, a device may be noted to be “hot pluggable”.

As used herein, “hot swap” may refer to the act of replacing, removing, or adding a component or components while the system is powered on and/or running. Further, hot swap may include the continued operation of the system without interruption. In other words, in response to a hot swap operation (for example, replacing one device with a new device), a system may operate as normal without interruption. Hot swap may also be referred to with terms such as, hot swappable, hot swapping, or hot swappability. In other words, a device may be noted to be “hot swappable”.

FIG. 1 is a block diagram of a converter board 100, according to an example. In an example, the converter board 100 may be a PCIe converter board. In such examples, a computing device with PCIe slots, sockets, interfaces, or connectors may accept the converter board 100. Further, the PCIe converter board (as in, the converter board 100) may be hot swappable, hot pluggable, or neither. In a further example, the PCIe card (or converter board 100) may include an option card or not include an option card. In the example where the PCIe converter board (or converter board 100) includes an option card, the PCIe converter board (or converter board 100) may be considered populated. In such examples, (as in, the PCIe converter board is populated) the PCIe converter board (or converter board 100) may be hot swappable, hot pluggable, or neither. In another example, where the PCIe converter board (or converter board 100) does not include an option card, the PCIe converter board (or converter board 100) may not be considered populated. In such examples, (as in, the PCIe converter board is unpopulated) the PCIe converter board (or converter board 100) may be hot swappable, hot pluggable, or neither regardless of how the PCIe converter board (or converter board 100) operates when populated.

As stated above, the end connector 106 may be a socket, slot, interface, or connector to connect to the option card. In a further example, the end connector 106 may be a SFF-TA-1002 connector. In another example, the end connector 106 may be a large form factor (LFF) connector. In such examples, the cutout may be larger than if the end connector 106 were a SFF-TA-1002 connector, due to the greater dimensions of a LFF option card. In another example, the end connector 106 may be, but is not limited to, a small computer system interface (SCSI) connector, an internet SCSI (iSCSI), a serial attached SCSI (SAS) connector, or a fibre channel connector.

As stated above, the guiderails 104 may accept and guide an option card. In other words, a user may insert an option card into the converter board 100 through the open end of the cutout 110. As the option card is inserted into the converter board 100, the sides of the option card may follow a gap or channel formed by the guiderails 104. In other words, the guiderails 104 may guide the option card to the end connector 106 of the converter board 100. In another example, at least one of the guiderails 104 may include a latch. In such examples, the latch may be utilized for a variety of purposes.

In an example, the latch noted above could be placed in a first position or a locked position. In such positions, the latch could, when there is no option card inserted into the converter board 100, prevent the addition of an option card. The purpose for preventing the addition of a new option card could be to prevent hot plugging of a non-hot pluggable option card. In such examples, inserting a non-hot pluggable option card into an operating, running, or executing computing device could damage the computing device. In a further example of the first position or locked position, the latch could, when there is an option card inserted into the converter board 100, lock the option card in place. The purpose for preventing removal of an option card could be to prevent hot swapping or removal of the option card. In such examples, removing a non-hot swappable option card from an operating, running, or executing computing device could damage the computing device and/or option card.

In another example, the latch noted above could be placed in a second position or an unlocked position. In such positions, the latch could, when there is no option card inserted into the converter board 100, allow the addition of an option card. For example, a user could move the latch to an unlocked position or remove the latch altogether when a computing device is shut down (thus allowing for addition of new components that are not hot pluggable or hot swappable). In another example, the option card may be hot swappable or hot pluggable. In such examples, the user could move the latch to an unlocked position, the user could remove the latch altogether, or the converter board 100 could by default come with the latch in an unlocked position (or removed altogether). In a further example of the second position or unlocked position, the latch could, when there is an option card inserted into the converter board 100, allow the option card to be removed from a computing device. For example, if a non-hot swappable or a non-hot pluggable option card were to experience some issue, a user could move the latch to the unlocked position or remove the latch altogether after the computing device is shut down.

In another example, the option card may be any type of card. For example, the option card may be a NIC, a machine-readable storage medium (such as a solid state drive, flash memory, a hard drive, or any storage related device), a controller, a data processing component, or any other networking component. In another example, the option card may be an OCP NIC 3.0.

In another example, the converter board 100 may include a metal bracket. In such examples, the metal bracket may be attached to the front converter board 100 via fasteners or other means. The metal bracket may add rigidity and/or stability to the converter board 100. The metal bracket may be used to push or pull the converter board 100 into or out of, respectively, a slot, connector, interface, or socket of a computing device. In another example, the metal bracket may include an opening, aperture, or threaded opening to allow for connection of a fastener. In such examples, an option card may include a fastener, such as a thumbscrew. Further, when the option card is fully inserted into converter board 100, the fastener included on the option card may connect to the opening, aperture, or threaded opening, thus securing the option card to the converter board 100.

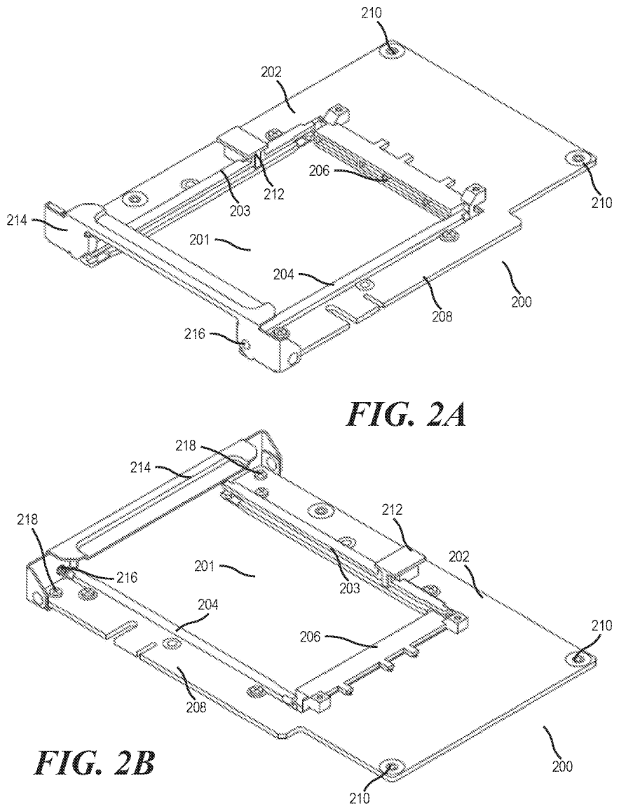

FIG. 2A is a schematic view of a converter board 200, according to an example. In such examples, the converter board 200 may be a PCIe board, as described above. Further, the converter board 200 may include an edge connector 208 to connect to a slot, connector, interface, or socket of computing device. In another example, the converter board may be comprised of a PCB 202. The PCB 202 may include a cutout 201, slot, or gap. The cutout 201, slot, or gap may include two opposing sides including guiderails 203, 204, an end including an end connector 206, and an opening opposite the end connector 206, the opening to allow insertion of an option card (not shown). In an example, the opening may be framed by a metal bracket 214. The metal bracket 214 may be attached directly to the PCB 202. The metal bracket 214 may also include an opening 216, aperture, or threaded opening to allow connection of a fastener (for example a screw or thumbscrew) of an option card.

In another example and as noted above, the two opposing sides may include guiderails 203, 204. In such examples, the guiderails 203, 204 may form a channel or groove. The channel or groove may accept the PCB of an option card. The guiderails 203, 204 may allow for ease of insertion of option card, as well as ensuring proper seating of the option card into the end connector 206. In a further example, at least one of the guiderails 203, 204 may include a latch 212. For example, guiderail 203 may include latch 212. As noted above, latch 212 could be used to prevent insertion of an option card and prevent removal of an option card.

In another example, various apertures 210 or openings may be located on the converter board 200. In such examples, the apertures 210 or openings may be utilized for various purposes. For example, screws or other fasteners may be added through the apertures 210 or openings to fasten a stiffener or bolster plate to the converter board 200, thus increasing the structural integrity of the converter board 200. In another example, screws or fasteners may be added through the apertures 210 or openings to attach the converter board 200 to the bottom tray of a computing device or a motherboard of the computing device.

FIG. 2B is another schematic view of the converter board 200, according to an example, As noted above, the converter board 200 may include a metal bracket 214. The metal bracket 214 may be attached directly to the converter board 200. As shown in FIG. 2B, the metal bracket 214 may attach to the converter board 200 via screws 218. Other fasteners may be utilized to attach the metal bracket 214 to the converter board 200.

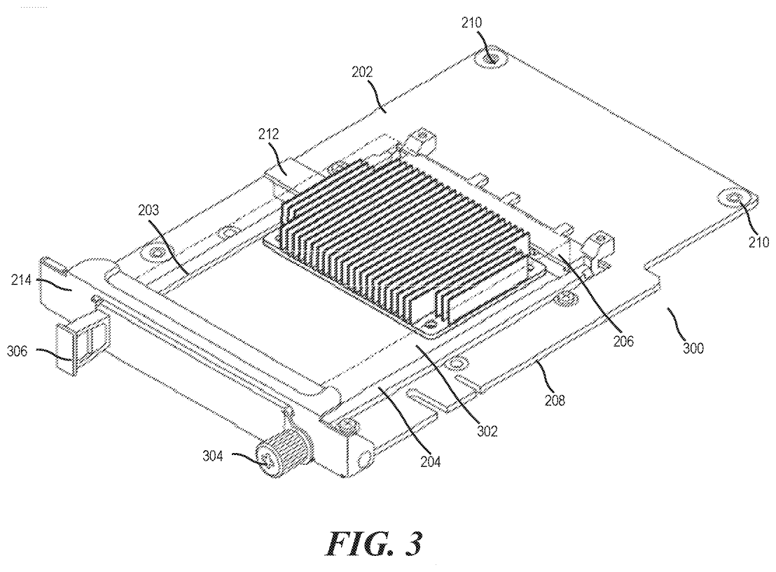

FIG. 3 is a schematic view of a converter board 300 with an option card 302, according to an example. As noted above, the converter board 300 may accept option cards 302. In an example, the option card 302 may include a grip 306. The grip 306 may be used to push or pull the option card 302 into or out of, respectively, the converter board 300. In another example, the option card 302 may include fastener, such as a thumbscrew 304. The fastener (as in, the thumbscrew 304) may connect to the opening, aperture, or threaded opening (not visible in FIG. 3) of the metal bracket 214. The fastener (as in, the thumbscrew 304) may secure the option card 302 to the converter board 300.

In another example and as noted above, the option card 302 may be a NIC, a machine-readable storage medium (such as a solid state drive, flash memory, a hard drive, or any storage related device), a controller, a data processing component, or any other networking component. In an example, the option card 302 may include a port. In another example, the option card 302 may include multiple ports. In another example, the option card 302 may include different types of ports. In another example, the option card 302 may not be higher than the highest point of the metal bracket 214. In a further example, the option card 302 height may be set or determined based on various factors, such as the amount of converter boards 300 to be installed in a computing device, the type of converter board 300 (for example, a mezzanine type or a riser type), and/or the type of the option card 302.

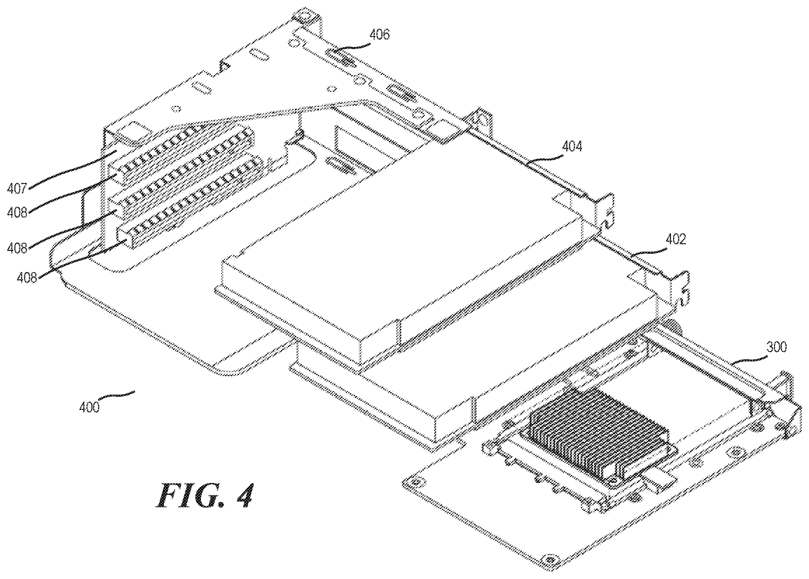

FIG. 4 is a schematic view of a portion of a computing device 400, a converter board 300, and other boards 402, 404, according to an example. In such examples, the portion of the computing device 400 show includes a riser card 407 (or riser board) and a riser cage 406. The riser card 407 (or riser board) may connect to the computing device via a connection on the motherboard (for example, a PCIe connection). The riser card 407 (or riser board) may include a various number of slots, connectors 408, interfaces, or sockets (FIG. 4 illustrates three connectors). Various boards may connect to the riser card 407 (or riser board). For example, one configuration may be one converter board 300 and two other boards 402, 404 (for example, two PCIe cards). In another example, all connectors 408 may be populated with converter boards 300. In another example, when a converter board 300 is connected to the riser card 407 (or riser board), the converter board 300 may not include an option card. After installation of a converter board 300 into the riser card 407 (or riser board), a user may add an option card to the converter board 300. Other configurations may include a mezzanine style connector (not shown).

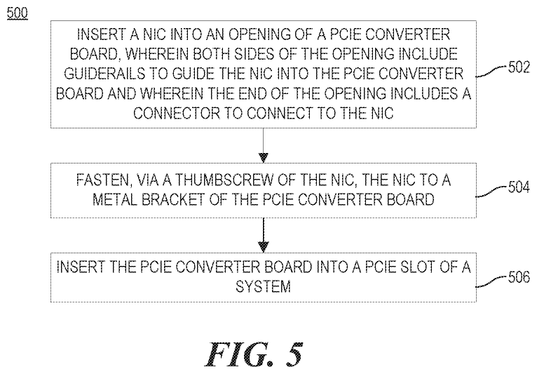

FIG. 5 is a flow chart of a method to install a network interface card (MC) into a peripheral component interconnect express (PCIe) converter board. Although execution of method 500 is described below with reference to the converter board 300 of FIG. 3, other suitable systems or boards may be utilized, including, but not limited to, converter board 100 or converter board 200. Additionally, implementation of method 500 is not limited to such examples.

At block 502, a user may insert an option card 302 (such as a NIC) into an opening of a converter board 300 (such as a PCIe converter board). The converter board 300 (e.g., the PCIe converter board) may include an opening. The option card 302 (e.g., the MC) may be inserted into the opening of the converter board 300 (e.g., the PCIe converter board). Additionally, the sides of the opening in the converter board 300 (e.g., the PCIe converter board) may include guiderails to ensure ease of installation of the option card 302 (e.g., the NIC), to guide the option card 302 (e.g., the MC) into the converter board 300 (e.g., the PCIe converter board), to ensure proper seating of the connection of the option card 302 (e.g., the NIC) in the end connector 206.

At block 504, a user may fasten, via a thumbscrew 304 or other connector to a metal bracket 214 attached to the converter board (e.g., the PCIe converter board). In an example, the bracket may be compose of a material other than metal, such as plastic. In another example, the thumbscrew 304 may secure the option card 302 (e.g., the NIC) to the metal bracket 214 and secure the option card 302 (e.g., the NIC) in the converter board 300 (e.g., the PCIe converter board).

At block 506, a user may insert the converter board 300 (e.g., the PCIe converter board) into a slot, connector, socket, or interface. In further example, the slot, connector, socket, or interface is a PCIe interface, In another example, the converter board 300 (e.g., the PCIe converter board) may be inserted into the slot, connector, socket, or interface (e.g., a PCIe interface) before the option card 302 (e.g., the NIC) is inserted into the converter board 300 (e.g., the PCIe converter board).

In another example, the option card 302 (e.g., the NIC) may fail or experience an issue. In such examples, a user may replace the option card 302 (e.g., the NIC) due to said failure and/or issue.

In the case that the option card 302 (e.g., the NIC) is hot swappable or hot pluggable, a user may remove the option card 302 (e.g., the NIC) while the computing device or system that the converter board 300 (e.g., the PCIe converter board) is installed in is still operating or running. To remove the option card 302 (e.g., the NIC), a user may move a latch 212 to a second position or unlocked position and then the user may remove the option card 302 (e.g., the NIC). Further, if the new option card to be installed is hot swappable or hot pluggable the new option card may be added at any time after the option card 302 (e.g., the NIC) experiencing the issue has been removed. Further, if the new option card to be installed is not hot swappable or hot pluggable the new option card may be added when the computing device or system that the converter board 300 (e.g., the PCIe converter board) is installed in is still operating or running.

In the case that the option card 302 (e.g., the NIC) is not hot swappable or hot pluggable, a user may remove the option card 302 (e.g., the NIC) when e the computing device or system that the converter board 300 (e.g., the PCIe converter board) is installed in is shut down or powered off. To remove the option card 302 (e.g., the NIC), as noted above, a user may move a latch 212 to a second position or unlocked position and then the user may remove the option card 302 (e.g., the NIC). Further, if the new option card to be installed is hot swappable or hot pluggable the new option card may be added at any time after the option card 302 (e.g., the NIC) experiencing the issue has been removed. Further, if the new option card to be installed is not hot swappable or hot pluggable the new option card may be added when the computing device or system that the converter board 300 (e.g., the PCIe converter board) is installed in is still operating or running.

Although the flow diagram of FIG. 5 shows a specific order of execution, the order of execution may differ from that which is depicted. For example, the order of execution of two or more blocks or arrows may be scrambled relative to the order shown. Also, two or more blocks shown in succession may be executed concurrently or with partial concurrence. All such variations are within the scope of the present disclosure.

The present disclosure has been described using non-limiting detailed descriptions of examples thereof and is not intended to limit the scope of the present disclosure. It should be understood that features and/or operations described with respect to one example may be used with other examples and that not all examples of the present disclosure have all of the features and/or operations illustrated in a particular figure or described with respect to one of the examples. Variations of examples described will occur to persons of the art. Furthermore, the terms “comprise,” “include,” “have” and their conjugates, shall mean, when used in the present disclosure and/or claims, “including but not necessarily limited to.”

It is noted that some of the above described examples may include structure, acts or details of structures and acts that may not be essential to the present disclosure and are intended to be examples. Structure and acts described herein are replaceable by equivalents, which perform the same function, even if the structure or acts are different, as known in the art. Therefore, the scope of the present disclosure is limited only by the elements and limitations as used in the claims

1. A converter board, comprising:
a printed circuit board, wherein the printed circuit board includes a cutout to form two opposing sides and an end;
a guiderail attached to each opposing end, wherein each guiderail forms a channel to accept a side of an option card;
an end connector attached to the end, the end connector to connect to the option card when the option card is fully inserted into the cutout; and
an edge connector to connect the converter board to a system, wherein the edge connector is connected to the end connector.

2. The converter board of claim 1, wherein the edge connector is a peripheral component interconnect express (PCIe) connector.

3. The converter board of claim 1, wherein the end connector is a small form factor-technology affiliate-1002 (SFF-TA-1002) connector.

4. The converter board of claim 1, wherein the end connector is a large form factor connector.

5. The converter board of claim 1, wherein the option card is a network interface card (NIC).

6. The converter board of claim 1, wherein one of the guiderails includes a latch.

7. The converter board of claim 6, wherein:
when the latch is in a first position, the latch prevents an option card from being inserted into the converter board; and
when the latch is in a second position, the latch allows an option card to be inserted into the converter board.

8. The converter board of claim 6, wherein the latch locks an option card into place when fully inserted into the converter board.

9. The converter board of claim 1, further comprising a metal bracket attached to a front of the converter board and opposite the end.

10. The converter board of claim 9, wherein the metal bracket includes an opening that allows the option card to attach to the metal bracket via a fastener.

11. A PCIe card, comprising:
an edge connector to connect to a PCIe slot;
an opening defined by a metal bracket, two opposing sides, and an end, wherein the metal bracket includes a space to allow an option card to be inserted into the PCIe card;
guiderails attached to the two opposing sides, wherein each guiderail forms a channel and each channel guides insertion of the option card into the PCIe card; and
a connector, to connect to the option card, attached to the end, wherein the connector is electrically connected to the edge connector.

12. The PCIe card of claim 11, wherein the metal bracket includes an opening to allow the option card to attach to the metal bracket via a fastener.

13. The PCIe card of claim 12, wherein the fastener is a thumbscrew.

14. The PCIe card of claim 11, wherein one of the guide rails includes a latch.

15. The PCIe card of claim 14, wherein:
when the latch is in a first position, the latch prevents an option card from being inserted into the converter board, and;
when the latch is in a second position, the latch allows an option card to be inserted into the converter board.

16. The PCIe card of claim 14, wherein the latch locks an option card into place when inserted into the converter board.

17. A method comprising:
inserting a NIC into an opening of a PCIe converter board, wherein both sides of the opening include guiderails, wherein the guiderails form channels to guide the NIC into the PCIe converter board and wherein the end of the opening includes a connector to connect to the NIC, and;
fastening, via a thumbscrew of the NIC, the NIC to a metal bracket of the PCIe card.

18. The method of claim 17, further comprising:
inserting the PCIe converter board into a PCIe slot of a system.

19. The method of claim 18, further comprising:
removing the NIC from the PCIe converter board while the system is powered on.

20. The method of claim 19, further comprising:
adding a new NIC to the PCIe converter board while the system is powered on.
